(19) United States
(12) Patent Application Publication
(10) Pub. No.: US 2025/0096028 A1
(43) Pub. Date: Mar. 20, 2025

(54) SUBSTRATE TREATING APPARATUS AND HEATING UNIT

(71) Applicant: SEMES CO., LTD., Cheonan-si (KR)

(72) Inventors: Ju Mi LEE, Seoul (KR); Min Young KIM, Hwaseong-si (KR); Jae Oh BANG, Seoul (KR); Yun Hwa HONG, Incheon-si (KR)

(73) Assignee: SEMES CO., LTD., Cheonan-si (KR)

(21) Appl. No.: 18/810,699

(22) Filed: Aug. 21, 2024

(30) Foreign Application Priority Data
Sep. 19, 2023 (KR) 10-2023-0124586

(51) Int. Cl. H01L 21/683; H01L 21/67; H01L 21/687

(52) U.S. Cl. CPC H01L 21/6838; H01L 21/67103; H01L 21/68742; H01L 21/6875

(57) ABSTRACT

Disclosed is a substrate treating apparatus including: a heating unit including a heating plate for supporting and heating a substrate; and a pressure reducing unit for applying a vacuum pressure to a space between a top surface of the heating plate and a substrate supported on the heating plate, in which the heating plate is provided with a lift hole, which is a movement passage for a lift pin to lift the substrate supported on the heating plate, and a top end of the lift hole is provided at a position higher than the top surface of the heating plate.

### CROSS-REFERENCE TO RELATED APPLICATIONS

This application claims priority to and the benefit of Korean Patent Application No. 10-2023-0124586 filed in the Korean Intellectual Property Office on Sep. 19, 2023, the entire contents of which are incorporated herein by reference.

### TECHNICAL FIELD

The present invention relates to a substrate treating apparatus for treating a substrate, and a heating unit.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

Here, the heat treatment process is carried out by transferring a substrate to a heat treating chamber and heating the transferred substrate. In this case, the substrate is mounted on a heating plate and is heat treated by receiving heat from the heated heating plate in the related art.

The heating plate adsorbs the substrate through a vacuum hole located on the bottom surface of the substrate so that the substrate is not deformed by thermal deformation during heat treatment.

In this case, in addition to the vacuum hole, a lift hole is formed in the heating plate for lifting the substrate when the substrate is transferred, and a lift pin is inserted into the lift hole that moves up and down, so that the lift hole is used to lift the substrate.

At this time, the vacuum hole suctions the bottom surface of the substrate to form a vacuum region on the bottom surface of the substrate, and the outside air on the lift hole side flows strongly to the vacuum hole side, which reduces the temperature of the substrate around the lift hole.

Therefore, the substrate is not heated uniformly throughout the substrate due to the lower temperature of the area around the lift hole, causing the substrate to bake unevenly.

Consequently, conventional heating plates process a number of partition walls on the heating plate to prevent abnormal airflow from forming on the bottom side of the substrate, but the partition walls formed on the heating plate generate residual stress on the heating plate during cutting processing, causing problems such as deformation of the heating plate such as warping or bending.

### SUMMARY OF THE INVENTION

The present invention has been made in an effort to provide a substrate treating apparatus and a heating unit that prevent a temperature of a substrate from decreasing around a lift hole in a heating unit that heats the substrate.

The present invention has also been made in an effort to provide a substrate treating apparatus and a heating unit that prevent residual stress from being generated in a heating plate when processing the heating plate that heats a substrate.

The present invention has also been made in an effort to provide a substrate treating apparatus and a heating unit that prevent an airflow that lowers a temperature of a substrate in a specific region area of a substrate from being generated when adsorbing the substrate while heat treating the substrate, and a heating unit.

The object of the present invention is not limited thereto, and other objects not mentioned will be clearly understood by those of ordinary skill in the art from the following description.

An exemplary embodiment of the present invention provides a substrate treating apparatus including: a heating unit including a heating plate for supporting and heating a substrate; and a pressure reducing unit for applying a vacuum pressure to a space between a top surface of the heating plate and a substrate supported on the heating plate, in which the heating plate is provided with a lift hole, which is a movement passage for a lift pin to lift the substrate supported on the heating plate, and a top end of the lift hole is provided at a position higher than the top surface of the heating plate.

According to the exemplary embodiment, the heating unit may further include a support pin provided on the top surface of the heating plate and supporting the substrate, and a top end of the lift hole may be provided at a height lower than a top end of the support pin.

According to the exemplary embodiment, the heating plate may be formed with a through-hole penetrating in an up and down direction, the heating unit may further include a blocking body in which the lift hole is formed, and the blocking body may be inserted into the through-hole.

According to the exemplary embodiment, the blocking body may be formed in a ring shape when viewed from above.

According to the exemplary embodiment, the blocking body may include a body portion, and an extension portion positioned below the body portion, the body portion may be inserted into the through-hole such that a partial region thereof protrudes upwardly from the heating plate, and when viewed from above, the extension portion may be positioned below the heating plate and has a larger area than the through-hole.

According to the exemplary embodiment, the blocking body may include a body portion, and an extension portion positioned on the body portion, the body portion may be inserted into the through-hole such that a partial region thereof protrudes upwardly from the heating plate, and when viewed from above, the extension portion may be positioned on the heating plate and has a larger area than the through-hole.

According to the exemplary embodiment, the blocking body may be detachably provided on the heating plate.

According to the exemplary embodiment, the blocking body may be formed of a material including a resin.

According to the exemplary embodiment, the heating unit may further include a ring-shaped outer wall formed by upwardly protruding from the top surface of the heating plate and formed near an edge of the heating plate.

According to the exemplary embodiment, an outer diameter of the outer wall may be greater than an outer diameter of the substrate and an inner diameter of the outer wall may be less than an outer diameter of the substrate.

According to the exemplary embodiment, a top end of the outer wall may be provided at the same height as a top end of the lift hole.

According to the exemplary embodiment, a height of a top end of the outer wall may be provided at a height lower than a height of a top end of the support pin.

According to the exemplary embodiment, the outer wall may extend from at least some of the regions of the heating plate to form a single part with the heating plate.

Another exemplary embodiment of the present invention provides a heating unit for supporting a substrate and heating the substrate, the heating unit including: a heating plate which is disposed under a substrate, heats the substrate, and is formed with a through-hole and a vacuum hole; a support pin coupled to a top surface of the heating plate and supporting the substrate; and a blocking body which is disposed on a top portion of the heating plate, is formed with a lift hole, and includes a body portion extending to the top portion of the heating plate at a height greater than a height of a top end of the through hole, and the lift hole is a movement passage for a lift pin for lifting a substrate supported on the heating plate, and a top end is provided at a height greater than the top surface of the heating plate.

According to the exemplary embodiment, a top end of the lift hole may be provided at a height lower than a top end of the support pin.

According to the exemplary embodiment, the blocking body may be inserted into the through-hole.

According to the exemplary embodiment, the blocking body may be formed in a ring shape when viewed from above.

According to the exemplary embodiment, the blocking body may be detachably provided on the heating plate.

According to the exemplary embodiment, the blocking body may be formed of a material including a resin.

Still another exemplary embodiment of the present invention provides a heating unit for supporting a substrate and heating the substrate, the heating unit including: a heating plate which is disposed under the substrate, heats the substrate, and is formed with through-holes and vacuum holes; a support pin coupled to a top surface of the heating plate and supporting the substrate; a ring-shaped outer wall formed by upwardly protruding from the top surface of the heating plate and formed near an edge of the heating plate; and a blocking body which is formed of a material including a resin and includes a body portion that is detachably connected with the heating plate, is inserted into the through-hole, is disposed in a top portion of the heating plate, is formed in a ring shape having a lift hole when viewed above, and is positioned in the top portion of the heating plate at a height greater than a height of a top end of the through hole, and an extension portion that extends laterally from the body portion and is pressed against or coupled to a bottom surface of the heating plate, and the lift hole has a top end provided at a position lower than a top end of the support pin, is a movement passage for a lift pin for lifting a substrate supported on the heating plate, and has the top end provided at a position higher than a top surface of the heating plate.

The present invention has the effect of preventing the temperature of the substrate from decreasing around the lift holes of the heating unit that heats the substrate.

Furthermore, the present invention has the effect of preventing residual stress from being generated when processing the heating plate that heats the substrate.

Furthermore, the present invention has the effect of generating a uniform airflow throughout the substrate so that the temperature of the substrate is not lowered in a specific region of the substrate when the substrate is adsorbed by vacuum.

The effect of the present invention is not limited to the foregoing effects, and non-mentioned effects will be clearly understood by those skilled in the art from the present specification and the accompanying drawings.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### BRIEF DESCRIPTION OF THE DRAWINGS

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view schematically illustrating one example of a heat treating chamber of FIG. 3 or FIG. 4.

FIG. 7 is a front view of the heat treating chamber of FIG. 6.

FIG. 8 is a cross-sectional view schematically illustrating one example of the liquid treating chamber of FIG. 3 or 4.

FIG. 9 is a cross-sectional view schematically illustrating one example of the heating unit illustrated in FIG. 7.

FIG. 10 is a cross-sectional view of a state in which a substrate is supported on a support pin in a state where an upper body of a cover illustrated in FIG. 9 moves upwardly.

FIG. 11 is a top plan view of the heating unit illustrated in FIG. 9 viewed from above.

FIG. 12 is a longitudinal cross-sectional view of the separated heating plate of the heating unit.

FIG. 13 is a perspective view of a blocking body illustrated in FIG. 12.

FIG. 14 is a longitudinal cross-sectional view of a modified example of the blocking body illustrated in FIG. 12.

FIG. 15 is a perspective view of the blocking body illustrated in FIG. 14.

FIG. 16 is a longitudinal sectional view of another modified example of the blocking body illustrated in FIG. 12.

FIG. 17 is a perspective view of the blocking body illustrated in FIG. 16.

FIG. 18 is a longitudinal sectional view with the blocking body illustrated in FIG. 12 removed.

FIG. 19 is a longitudinal sectional view of still another modified example of the blocking body illustrated in FIG. 12.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

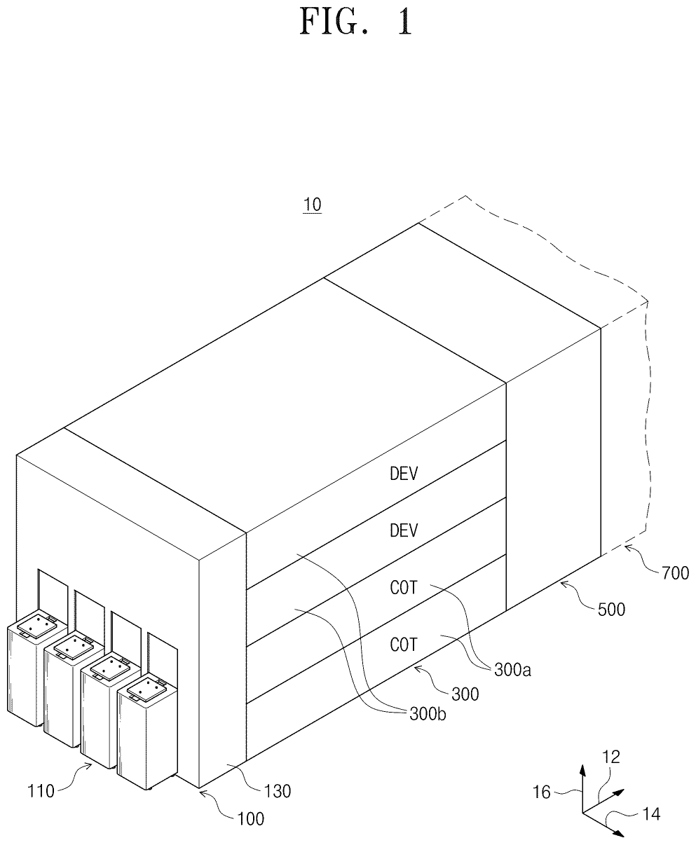

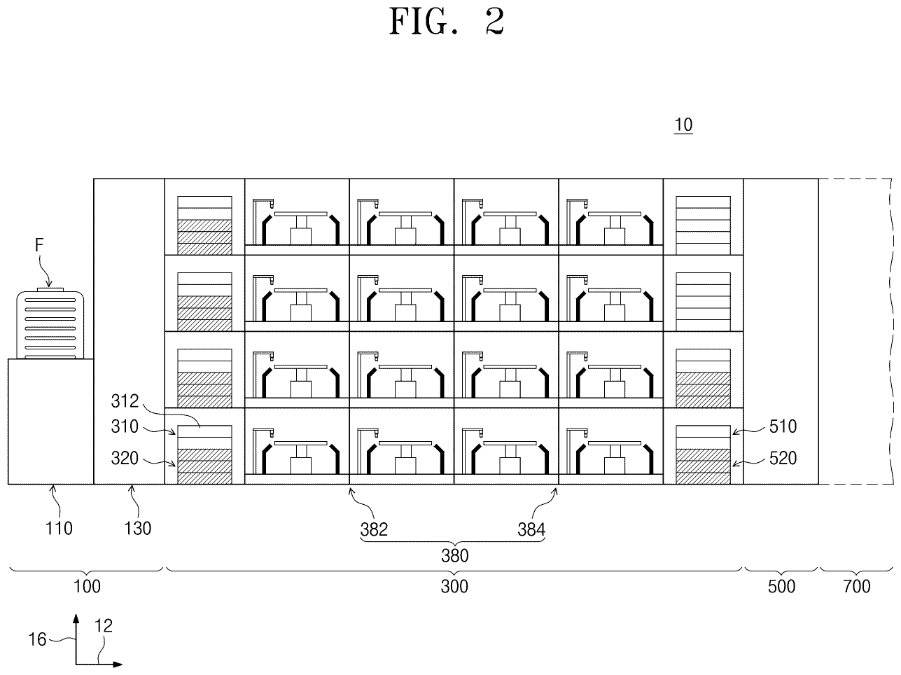

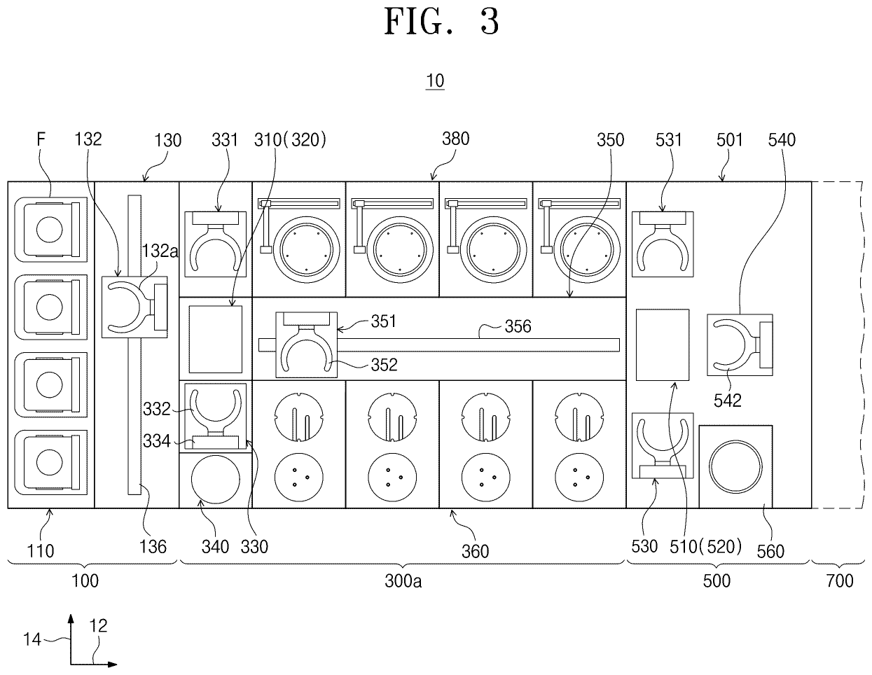

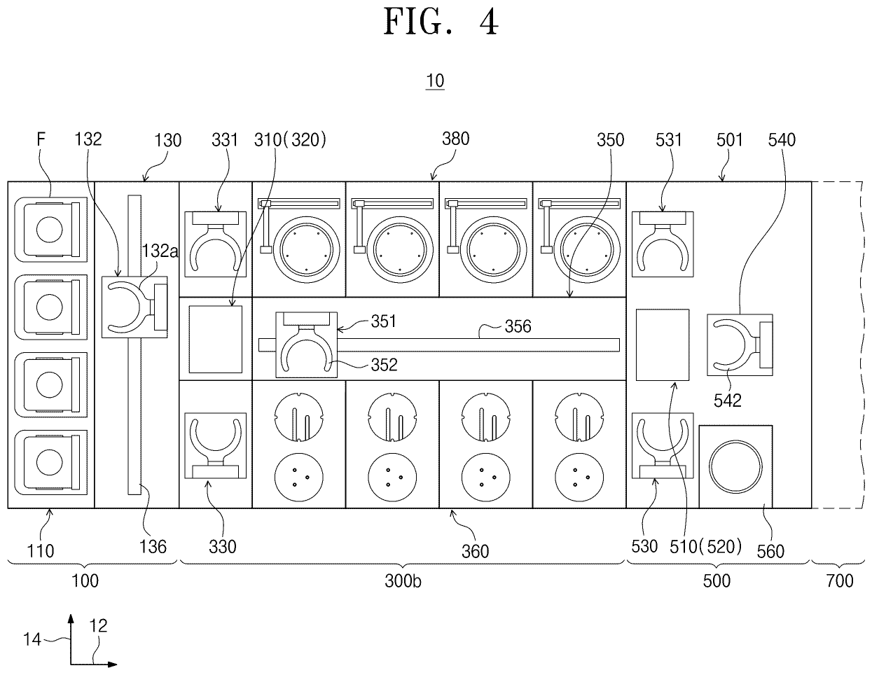

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 relative to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be positioned below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided relative to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side by side along the first direction 12. Optionally, some of the liquid treating chambers 360 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the application block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the application block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber 380 performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

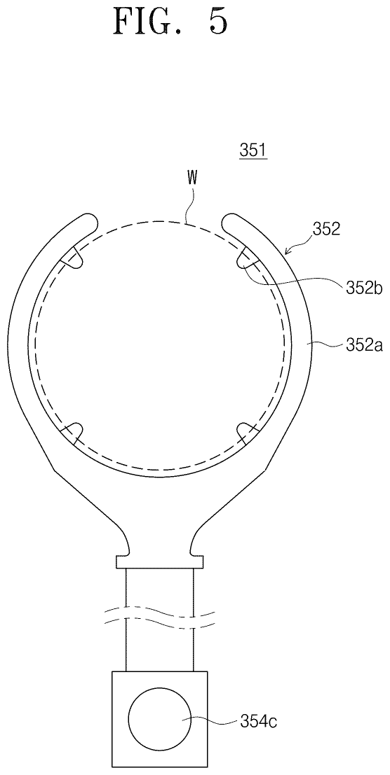

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

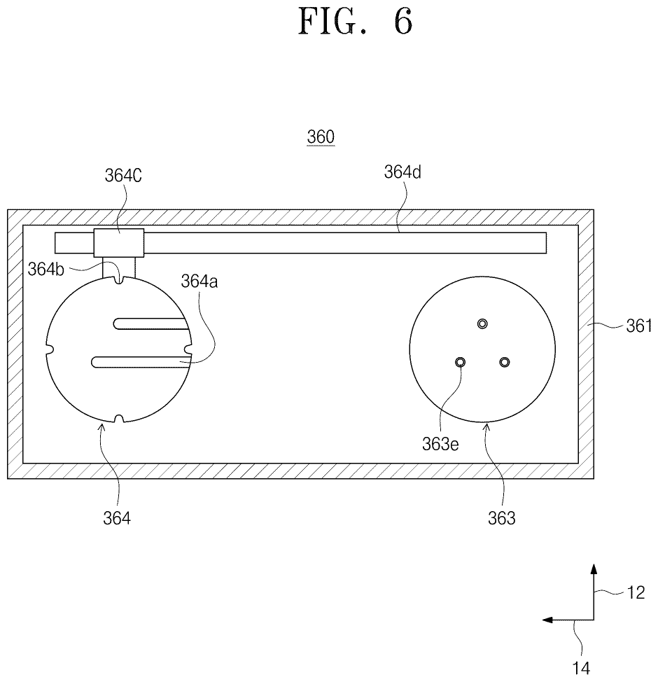

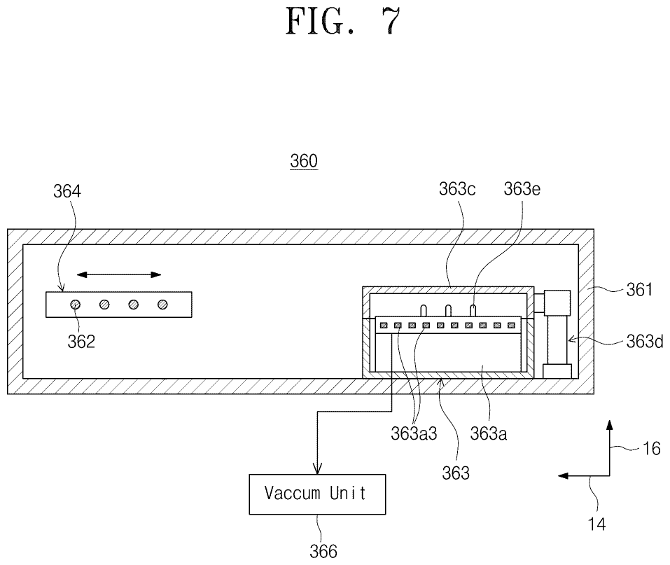

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, a transfer plate 364, an exhaust member 365, and a pressure reducing unit 366.

The housing 361 is provided in the shape of a generally rectangular parallelepiped. In the sidewall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 363 supports the liquid-treated substrate W and heats the liquid-treated substrate W. The heating unit 363 may receive the substrate W from the transfer plate 364. The heating unit 363 may be formed as a separate chamber for vapors generated during heating to be discharged to the outside. One example of the heating unit 363 will be described in more detail later.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands of the transfer robot 352 described above. Further, the notches 364b are provided in a number corresponding to the protrusions 352b formed on the hand, and are formed at locations corresponding to the protrusions 352b. In a position in which the hand and the transfer plate 364 are arranged in the vertical direction, the substrate W is transferred between the hand 354 and the transfer plate 364 when the vertical position of the hand and the transfer plate 364 is changed. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and lift pins 363e from interfering with each other when the substrate W is transferred between the transfer plate 364 and the heating unit 363.

The transfer plate 364 is provided with a thermally conductive material. In one example, the transfer plate 364 may be provided from a metal material.

A cooling flow path is formed within the transfer plate 364. The cooling flow path is supplied with cooling water. The substrate W, which has been completely heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Additionally, optionally, a cooling unit (not illustrated) may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

The exhaust member 365 forces exhaust inside a heat treatment space S363. The exhaust member 365 includes an exhaust pipe 365a, a pressure reducing member 365b, and a guide plate 365c.

The exhaust pipe 365a has a tubular shape with a through-hole 365al formed on an inner side. The exhaust pipe 365a is disposed so that the longitudinal direction of the pipe is oriented in a vertical up and down direction. The exhaust pipe 365a is positioned to penetrate an upper wall of the upper body 363c1. In one example, a lower end of the exhaust pipe 365a may be positioned within the heat treatment space S363 and a top end of the exhaust pipe 365a may be positioned outside of the heat treatment space S363.

The pressure reducing member 365b is connected to the top end of the exhaust pipe 365a to decompress the heat treatment space S363 through the exhaust pipe 365a. As one example of the pressure reducing member 365b, the pressure reducing member 365b may be formed of an exhaust pump or a vacuum pump.

The guide plate 365c is connected to the lower end of the exhaust pipe 365a near its center. The guide plate 365c has the shape of a circular plate extending from the bottom end of the exhaust pipe 365a. The guide plate 365c is fixedly coupled to the exhaust pipe 365a such that the through-hole 365al and the interior of the exhaust pipe 365a communicate with each other. The guide plate 365c is positioned at the top of the heating plate 363a while facing the support surface of the heating plate 363a. The guide plate 365c is positioned higher than the lower body 363c2. In one example, the guide plate 365c may be positioned at a height that faces the upper body 363c1. When viewed from above, the guide plate 365c is positioned to overlap an inlet hole 363c1b and has a diameter that is spaced apart from the inner surface of the upper body 363c1. This creates a gap between a side end of the guide plate 365c and the inner surface of the upper body 363c1, and the gap is provided as a flow path for airflow introduced through the inlet hole 363c1b to be supplied to the substrate W.

The pressure reducing unit 366 is connected to a vacuum hole 363a2 of the heating unit 363, and generates suction force on the vacuum hole 363a2 to form a vacuum region on the bottom surface of the substrate W. Thus, when the substrate W is heated by being supported on the heating unit 363, the substrate W may be seated in a non-flowing state by the vacuum region formed by the pressure reducing unit 366. The pressure reducing unit 366 may include a vacuum pump (not illustrated) forming suction force and a line (not illustrated) connecting the vacuum pump (not illustrated) to a vacuum hole.

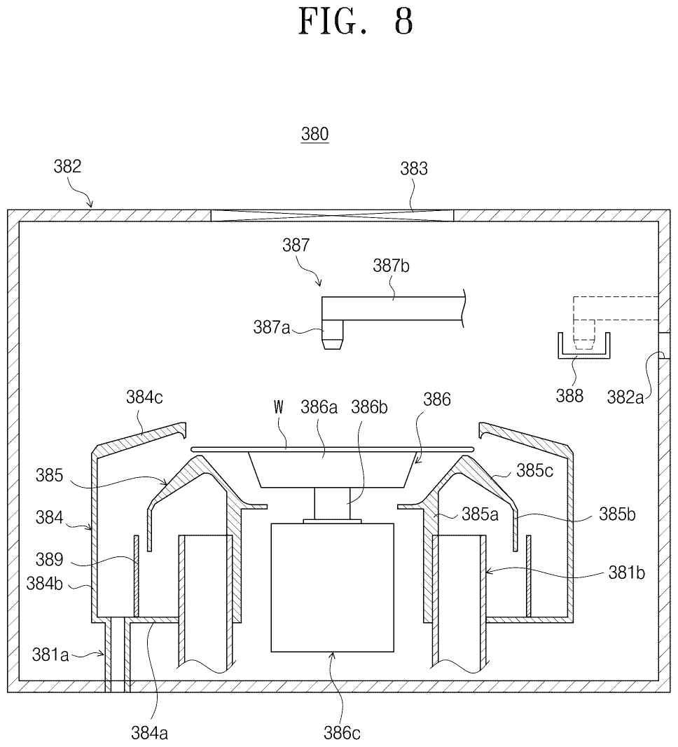

FIG. 8 is a front view schematically illustrating the liquid treating chamber of FIG. 3 or 4.

Referring to FIG. 8, the liquid treating chamber 380 includes a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

The support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

On the top wall of the housing 382 is disposed a fan filter unit 383 that supplies a downward airflow to the inner space. The fan filter unit 383 has a fan that introduces air from the outside into the inner space and a filter that filters the air from the outside.

The outer cup 384 has a bottom wall 384a, a sidewall 384b, and a top wall 384c. The inner of the outer cup 384 is provided as an inner space described above. The inner space H includes a treatment space at the top and an exhaust space at the bottom.

The bottom wall 384a is provided in a circular shape and has an opening in the center. The sidewall 384b extends upwardly from the outer end of the bottom wall 384a. The sidewall 384b is provided in a ring shape and is provided vertical to the bottom wall 384a. In one example, the sidewall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the sidewall 384b toward the center axis of the outer cup 384.

The guide cup 385 is positioned on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the sidewall 384b of the outer cup 384. The inner wall 385a is spaced upwardly from the bottom wall 384a of the outer cup 384. The top wall 385c connects the top end of the outer wall 385b with the top end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. A gas-liquid separation plate 389 may be provided to extend upwardly from the bottom wall 384a of the outer cup 384. The gas-liquid separation plate 1230 may be provided in a ring shape. The gas-liquid separation plate 389 may be positioned between the sidewall 384b of the outer cup 384 and the outer wall 385b of the guide cup 385 when viewed from above. The top end of the gas-liquid separation plate 389 may be positioned lower than the bottom end of the outer wall 385b of the guide cup 385.

The bottom wall 384a of the outer cup 384 is connected to an outlet pipe 381a for discharging the treatment liquid and an exhaust pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

The interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided relative to the buffer unit 510.

The interface robot 540 is disposed between the buffer unit 510 and the exposure device 700. The interface robot 540 is provided to transfer the substrate W between the buffer unit 510, the cooling unit 520, the additional process chamber 560, and the exposure unit 700. The interface robot 540 has a hand 542 on which the substrate W is placed, and the hand 542 may be provided to be movable forwardly and backwardly, rotatable about an axis parallel to the third direction 16, and movable along the third direction 16.

The additional treating chamber 560 may perform a predetermined additional process before the substrate W, which has been completely processed in the applying block 300a, is loaded into the exposing device 700. Optionally, the additional treating chamber 420 may perform a predetermined additional process before the substrate W, which has been completely processed in the exposing device 700, is loaded into the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 is provided, and may be provided to be stacked on each other.

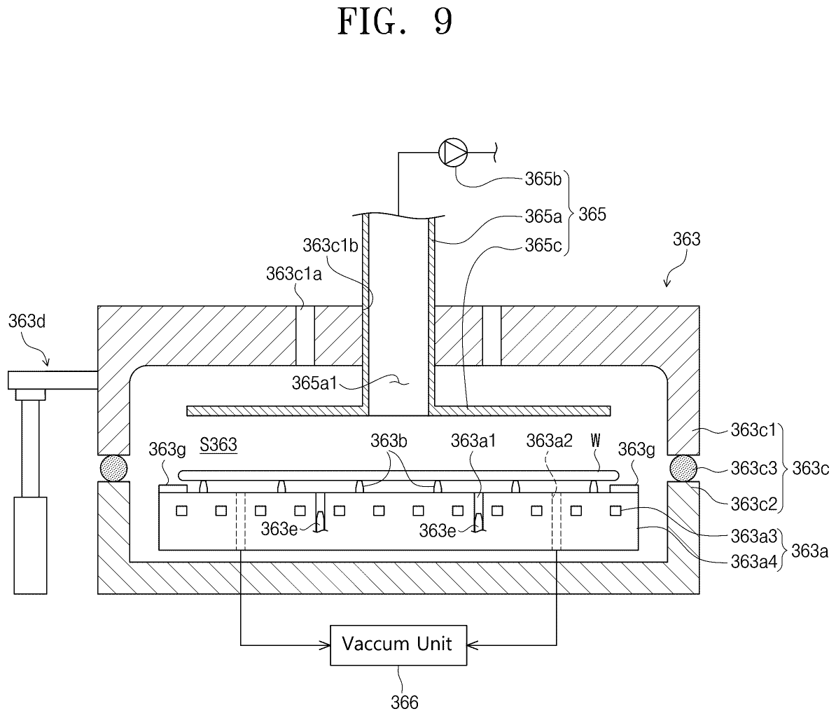

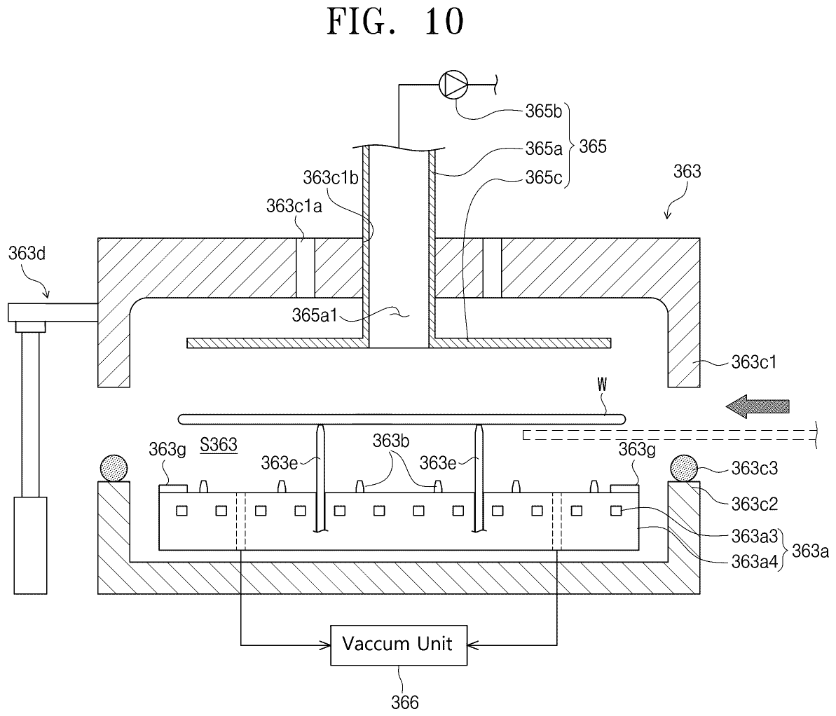

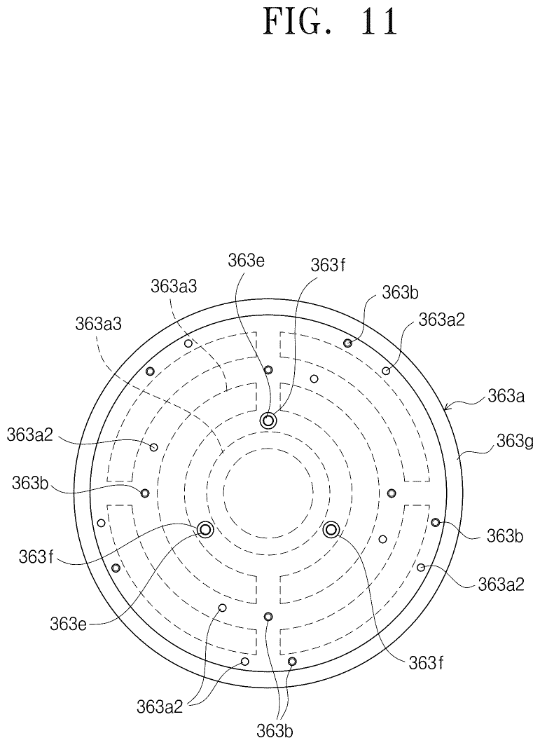

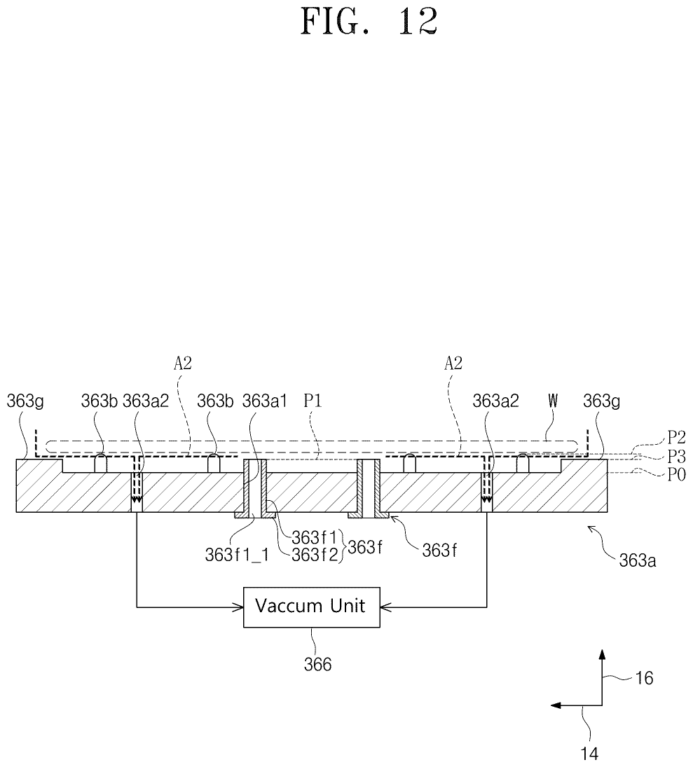

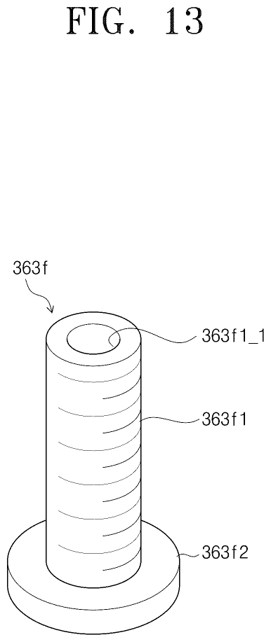

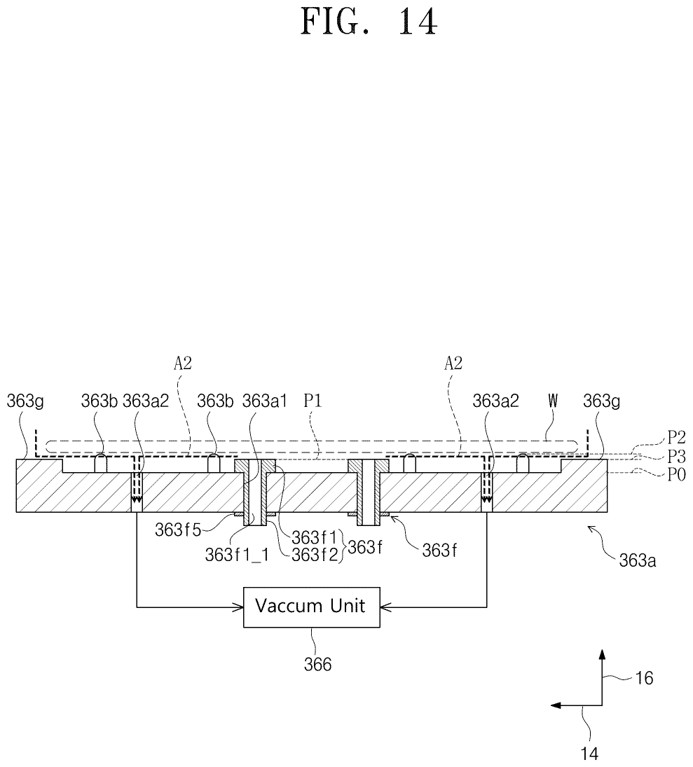

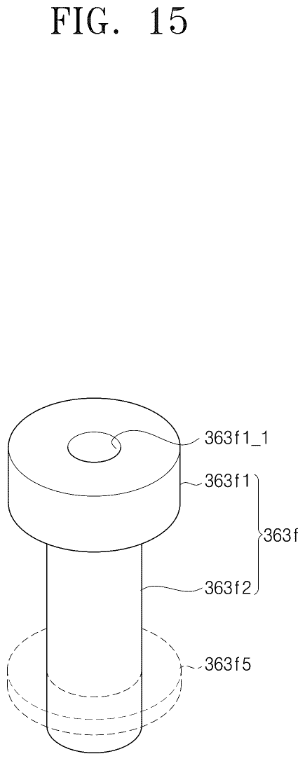

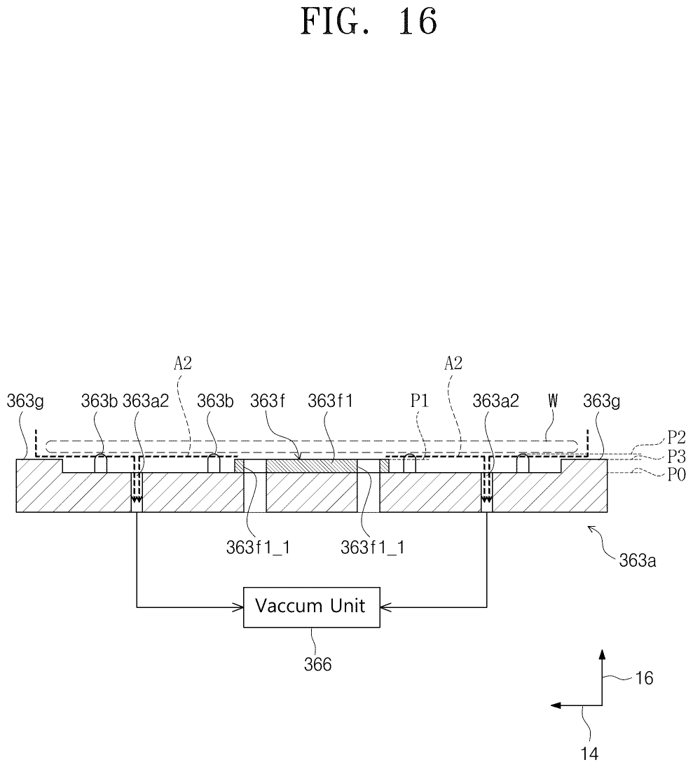

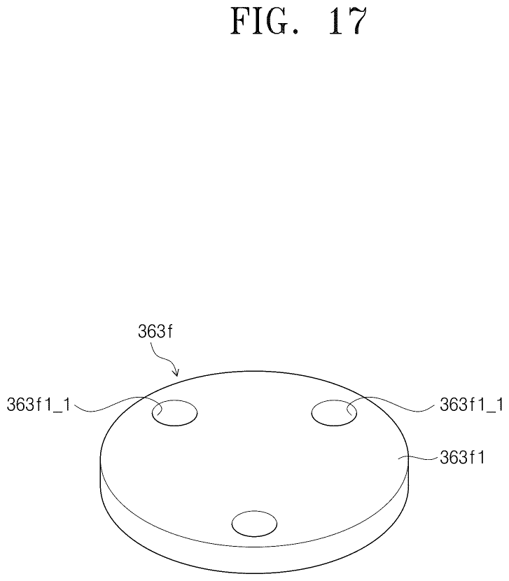

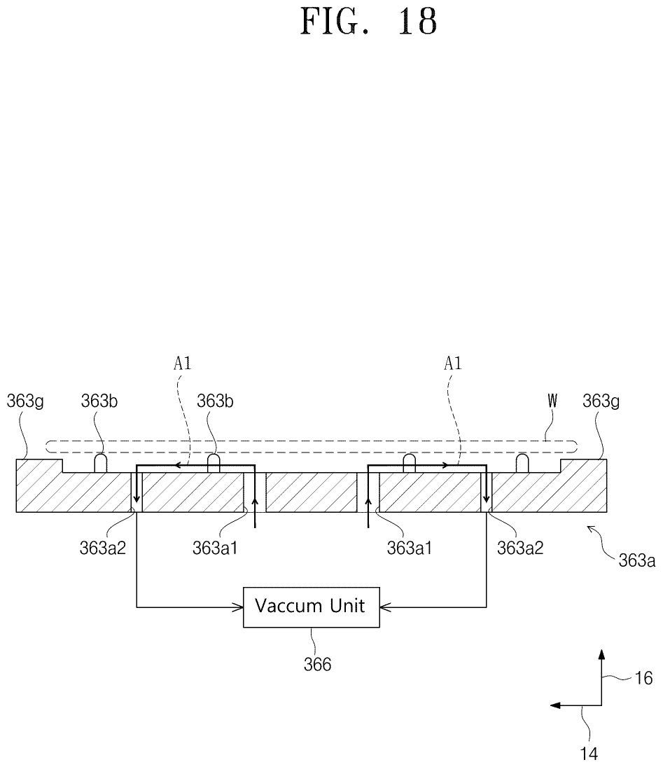

FIG. 9 is a cross-sectional view schematically illustrating one example of the heating unit illustrated in FIG. 7. FIG. 10 is a cross-sectional view of a state in which a substrate is supported on a support pin in a state where an upper body of a cover illustrated in FIG. 9 moves upwardly. FIG. 11 is a top plan view of the heating unit illustrated in FIG. 9 viewed from above. FIG. 12 is a longitudinal sectional view of the separated heating plate of the heating unit. FIG. 13 is a perspective view of a blocking body illustrated in FIG. 12. FIG. 14 is a longitudinal sectional view of a modified example of the blocking body illustrated in FIG. 12. FIG. 15 is a perspective view of the blocking body illustrated in FIG. 14. FIG. 16 is a longitudinal sectional view of another modified example of the blocking body illustrated in FIG. 12. FIG. 17 is a perspective view of the blocking body illustrated in FIG. 16. FIG. 18 is a longitudinal sectional view with the blocking body illustrated in FIG. 12 removed.

Referring to FIGS. 9 to 18, as an example of the heating unit 363, the heating unit 363 may include a heating plate 363a and a support pin 363b.

The heating plate 363a supports the liquid-treated substrate W and heats the liquid-treated substrate W. In this case, the liquid-treated substrate W may be transferred from the transfer plate 364. The heating plate 363a has a substantially circular shape when viewed above. The heating plate 363a may have a larger diameter than the substrate W. In this case, the diameter of the substrate W may be from 200 mm to 300 mm, for example. In one example, the heating plate 363a may include a plate 363a4 that supports the substrate W. In addition, the heating plate 363a may further include heating wires 363a3 that are heated when receiving power. Here, no heating wires 363a3 are illustrated in FIGS. 12 to 18, but the heating wires 363a3 may be configured to be included in the heating plate 363a of FIGS. 12 to 18. The heating wires 363a3 may be located on the inner side or the lower portion of the heating plate 363a. Further, the heating wires 363a3 may be formed in a pattern such that each of the plurality of heating wires 363a3 uniformly heats the entire substrate W when viewed from top to bottom. In this case, each of the heating wires 363a3 is positioned in the same plane. Further, each of the heating wires 363a3 may heat different areas of the seating surface at different temperatures. For example, some of the heat wires 363a3 may heat a center region of the heating plate 363a at a first temperature, and other of the heat wires 363a3 may heat an edge region of the heating plate 363a at a second temperature. The second temperature may be higher than the first temperature. In this case, the heated heating plate 363a may heat the liquid-treated substrate W to soft-bake or hard-bake the liquid.

Furthermore, the heating plate 363a may be provided with a plurality of through-holes 363al in which a blocking body 363f described later is inserted or in which the lift pin 363e is inserted. In this case, the through-holes 363al are each spaced apart from the center of the heating plate 363a at regular intervals when viewed from above. Further, the through-holes 363al are spaced apart from each other along the circumferential direction. In this case, the through-holes 363al may be equally spaced apart from each other. For example, the through-holes 363al may be provided in threes.

Further, the heating plate 363a may be provided with the plurality of vacuum holes 363a2. The vacuum holes 363a2 may be configured in the form communicating through the top portion and the bottom portion of the heating plate 363a. In this case, the vacuum holes 363a2 may be positioned to be closer to the edges of the substrate W than the positions of the through-holes 363al. The vacuum holes 363a2 may be utilized as a passage for air to be sucked during the decompression of the pressure reducing unit 366, thereby adsorbing the bottom surface of the substrate W. In addition, the vacuum hole 363a2 is positioned on an inner side of an outer wall 363g, which is to be described later, to form a vacuum region for adsorbing the bottom surface of the substrate W between the inner space of the outer wall 363g and the top surface of the heating plate 363a and the bottom surface of the substrate W.

The support pin 363b may be formed by protruding from the top surface of the heating plate 363a toward the bottom surface of the substrate W. The support pin 363b prevents the substrate W from directly contacting the top surface of the heating plate 363a. The support pin 363b is provided in the shape of a pin with a longitudinal direction parallel to the lift pin 363e. For example, the support pin 363b may be formed with a length from the bottom to the top of 100 to 150 μm. Furthermore, the support pins 363b are provided in a plurality, each of which is fixedly installed on the top surface of the heating plate 363a. The support pins 363b are positioned to protrude upwardly from the top surface of the heating plate 363a. The top end of the support pin 363b is provided with a contact surface that directly contacts the bottom surface of the substrate W, and the contact surface has an upwardly convex shape. Thus, the contact area between the support pin 363b and the substrate W can be minimized.

In addition, the heating unit 363 may further include a cover 363c.

The cover 363c includes an upper body 363c1, a lower body 363c2, and a sealing member 363c3.

The upper body 363c1 is provided in the shape of a barrel with an open bottom portion. An exhaust hole 363c1a and an inlet hole 363c1b are formed on the top surface of the upper body 363c1. The exhaust hole 363c1a is formed in the center of the upper body 363c1. The exhaust hole 363c1a evacuates the atmosphere of the heat treatment space S363. A plurality of inlet holes 363c1b is provided to be spaced apart and is arranged to surround the exhaust holes 363c1a. The inlet holes 363c1b introduce an external airflow into the heat treatment space S363. In one example, there are four inlet holes 363c1b, and the external airflow may be air.

The lower body 363c2 is provided in the shape of a barrel with an open top. A portion of the sidewall of the lower body 363c2 is provided as a gas inlet 1600 through which external gas is introduced into the treatment space. The lower body 363c2 is positioned below the upper body 363c1. The upper body 363c1 and the lower body 363c2 are positioned to face each other in an up and down direction. The upper body 363c1 and the lower body 363c2 are combined with each other to form the heat treatment space S363 inside. The upper body 363c1 and the lower body 363c2 are positioned such that their center axes are aligned with each other with respect to the up and down direction. The lower body 363c2 may have the same diameter as the upper body 363c1. That is, the top end of the lower body 363c2 may be positioned opposite the bottom end of the upper body 363c1.

One of the upper body 363c1 and the lower body 363c2 is moved to the open position and the blocking position by a driver 363d, and the other is fixed in its position. In the present exemplary embodiment, the position of the lower body 363c2 is fixed, and the upper body 363c1 is moved. The open position is a position in which the upper body 363c1 and the lower body 363c2 are spaced apart from each other so that the heat treatment space S363 is open. The closed position is a position in which the heat treatment space S363 is sealed from the outside by the lower body 363c2 and the upper body 363c1.

The sealing member 363c3 is positioned between the upper body 363c1 and the lower body 363c2. The sealing member 363c3 ensures that the treatment space is sealed from the outside when the upper body 363c1 and the lower body 363c2 are in contact with each other. The sealing member 363c3 may be provided in the shape of an annular ring. The sealing member 363c3 may be fixedly coupled to the top end of the lower body 363c2.

Further, the heating unit 363 may further include the lift pin 363e.

The lift pin 363e is provided to pass through a lift hole 363f1_1 of the second body 363f, which will be described later. Additionally, the lift pin 363e may be provided to pass through the through-hole 363al of the heating plate 363a, as desired. The lift pin 363e is provided to be movable in an up and down direction along the third direction 16. The lift pin 363e receives the substrate W from the transfer robot 351 and places the received substrate W down on the heating plate 363a, or lifts the substrate W from the heating plate 363a and hands the substrate W back to the transfer robot 351. According to the example, three lift pins 363e may be provided. The lift pin 363e has the driver (not illustrated) connected to its lower end, and may be moved in an up or down direction by driving of the driver (not illustrated).

In addition, the heating unit 363 may further include the blocking body 363f. The blocking body 363f may be formed by projecting a wall onto the heating plate 363a such that the top end of the lift hole 363f1_1 is higher than the top surface of the heating plate 363a, or may be configured in a form in which a separate member is placed on the heating plate 363a. The blocking body 363f blocks at least a portion of the outside air introduced through the lift hole 363f1_1 from entering the vacuum region, thereby forming an airflow A2 in which the outside air entering through the lift hole 363f1_1 is minimized. Thus, a strong airflow toward the lift hole 363f1_1 is prevented from forming at the bottom of the center of the substrate W, and thus the substrate W does not experience a drop in the center temperature. When the blocking body 363f is not configured as illustrated in FIG. 18, when the pressure reducing unit 366 is driven, the airflow A1 is formed from the through hole 363al to the vacuum hole 363a2 side, and in this case, the temperature of the substrate W near the center where the through hole 363al is located is lower than the temperature of other region, causing a problem that the substrate W is not baked uniformly as a whole. Furthermore, when the pressure reducing unit 366 sucks in the substrate W to form a vacuum region on the bottom surface of the substrate W, the blocking body 363f reduces the airflow A2 flowing toward the lift hole 363f1_1 so that the suction force for sucking in the substrate W does not become weak.

As one example of the blocking body 363f, the blocking body 363f may include a body portion 363f1.

The body portion 363f1 may be formed in a cylindrical or ring shape. For example, the body portion 363f1 may be formed as a cylinder, as illustrated in FIGS. 12 and 13, or as a ring, as illustrated in FIGS. 16 and 17. In this case, the body portion 363f1 may be formed with at least a portion of the region protruding over the top of the heating plate 363a such that a top end P1 is formed at a higher position than a top end P0 of the through-hole 363al. For example, the body portion 363f1 may be formed by protruding by a length of 70 to 100 m in an upward direction from the top surface of the heating plate 363a.

In addition, the body portion 363f1 has a lift hole 363f1_1 that penetrates from top to bottom near the center of the body portion. Further, the top end P1 of the lift hole 363f1_1 is positioned higher than the top end P0 of the through hole 363al, and is positioned higher than the top surface height P0 of the heating plate 363a. Therefore, the airflow sucked in by the pressure reducing unit 366 does not flow directly into the lift hole 363f1_1 side, thus preventing the center temperature of the substrate W from dropping.

Further, the body portion 363f1 is positioned such that the top end P1 is lower than the top end P2 of the support pin 363b. Therefore, since the body portion 363f1 does not interfere with the bottom surface of the substrate W supported on the support pin 363b, the heating plate 363a can uniformly bake the entire substrate W while keeping the distance from the substrate W constant.

Further, the body portion 363f1 may be in the shape of a ring having the lift hole 363f1_1 when viewed from above. Accordingly, the body portion 363f1 may enclose the entire top outer surface of the lift hole 363f1_1, thereby preventing the airflow from entering the lift hole 363f1_1 from the vacuum hole 363a2.

Furthermore, the body portion 363f1 may be at least partially inserted into the through-hole 363al. Thus, the heating plate 363a does not need to be processed to form the body portion 363f1 separately or to specify the position of the body portion 363f1, so that deformation, such as warping or bending, of the substrate W due to processing may not occur. In this case, the body portion 363f1, when inserted into the through-hole 363al, may be fit and engaged with the through-hole 363al, threaded with the through-hole 363al by being threaded on the outer circumference, or bonded to the through-hole 363al. In this case, the blocking body 363f may be formed in numbers corresponding to the number of the plurality of through-holes 363al.

In addition, the blocking body 363f may further include an extension portion 363f2.

The extension portion 363f2 extends one side from the body portion 363f1 and is seated on or is coupled to one side of the heating plate 363a. For example, the extension portion 363f2 may be formed to extend laterally from near the bottom center of a side of the body portion 363f1, as illustrated in FIGS. 12 and 13, or may be formed to extend laterally from near the top center of a side of the body portion 363f1, as illustrated in FIGS. 14 and 15. In this case, the extension portion 363f2 may be pressed against the bottom surface of the heating plate 363a, as illustrated in FIGS. 12 and 13, or may be seated on the top surface of the heating plate 363a, as illustrated in FIGS. 14 and 15. Accordingly, the body portion 363f1 can be positioned for engagement with the heating plate 363a by a position in which the extension portion 363f2 is seated on or is pressed against the heating plate 363a, thereby facilitating assembly and enabling precise engagement of the engagement plate. Furthermore, the extension portion 363f2 may be coupled to the heating plate 363a by a separate coupling member (not illustrated). The coupling member (not illustrated) may be formed of a bonding material that bonds between the extension portion 363f2 and the heating plate 363a. Further, the coupling member (not illustrated) may be formed as a fastening member, such as a bolt, that penetrates the extension portion 363f2 and the heating plate 363a. Further, the coupling member (not illustrated) may be formed as a fastening member 363f5, such as a C-ring, that is fastened to the outer circumference of the extension portion 363f2 or the body portion 363f1.

Furthermore, the blocking body 363f including the body portion 363f1 and the extension portion 363f2 as described above may be detachably provided with the heating plate 363a. Accordingly, the heating plate 363a may not be constructed by separately processing the blocking body 363f on the heating plate 363a, which reduces processing costs and prevents the problem of the heating plate 363a being deformed due to changes in stress during cutting processing of the heating plate 363a.

Furthermore, the blocking body 363f may be formed of a material including a resin. For example, the blocking body 363f may be formed of a material including a fluorine resin, rubber, or Teflon. Accordingly, by being formed including a resin, the blocking body 363f can minimize scratches or abrasions caused by collisions during insertion into the through-hole 363al or engagement with the heating plate 363a. Furthermore, the blocking body 363f can minimize friction with the lift pin 363e that is inserted into the lift hole 363f1_1 to ensure that the lifespan of the lift pin 363e is not reduced.

On the other hand, the heating plate 363a needs be made so that the heating plate 363a is not warped or is not bent due to residual stresses generated during machining. Accordingly, the heating plate 363a may be formed so that the heating plate is not warped or bent due to residual stresses generated during processing by making the heating plate 363a have a thickness of more than 2.3 mm. However, when the heating plate 363a is not more than 2.3 mm thick, the problem of warping or bending due to residual stresses generated during processing needs to be considered.

Accordingly, the heating unit 363 may further include an outer wall 363g.

The outer wall 363g is formed on a top portion of the heating plate 363a. The outer wall 363g may be formed by projecting upwardly from the top surface of the heating plate 363a. For example, the outer wall 363g may protrude upwardly from the top surface of the heating plate 363a for a length of 70 to 100 μm. Additionally, the outer wall 363g may be provided as an annularly shaped ring near an edge of the heating plate 363a when viewing the heating plate 363a from top to bottom. Since the outer wall 363g is formed by protruding from the heating plate 363a, the outer wall 363g prevents a large airflow from occurring near the edge of the substrate W, thereby preventing the heating temperature near the edge of the substrate W from decreasing. Furthermore, the outer wall 363g is formed by protruding upwardly near the edge of the heating plate 363a to prevent the heating plate 363a from being subjected to deformation of bending and warping by residual stresses during processing of the heating plate 363a.

Furthermore, the outer wall 363g may extend from at least some of the regions of the heating plate 363a to form a single part with the heating plate 363a, thereby minimizing deformation due to residual stresses generated during machining of the heating plate 363a.

In this way, the outer wall 363g minimizes the deformation due to residual stress generated during processing, and in this case, the top surface of the heating plate 363a is provided with an additional wall (not illustrated) that does not protrude between the outer wall 363g and the support pin 363b, which can reduce the manufacturing cost of the heating plate 363a.

Furthermore, the outer wall 363g is formed so that the outer diameter is larger than the outer diameter of the substrate W and the inner diameter is smaller than the outer diameter of the substrate W, so that deformation due to residual stress during processing of the heating plate 363a is minimized as much as possible.

Furthermore, the top height P3 of the outer wall 363g is formed at a height less than the height P2 of the support pin 363b. Furthermore, the top height P3 of the outer wall 363g is located at a lower height than the bottom surface of the substrate W. Therefore, a gap is generated between the outer wall 363g and the bottom surface of the substrate W. As a result, when airflow is sucked into the vacuum hole 363a2, airflow is generated from the outside of the substrate W through the gap to the vacuum hole 363a2. Therefore, the outer wall 363g maintains the vacuum pressure applied to the substrate W while preventing airflow from being generated from the through hole 363al to the vacuum hole 363a2 as much as possible, thereby heating the substrate W stably.

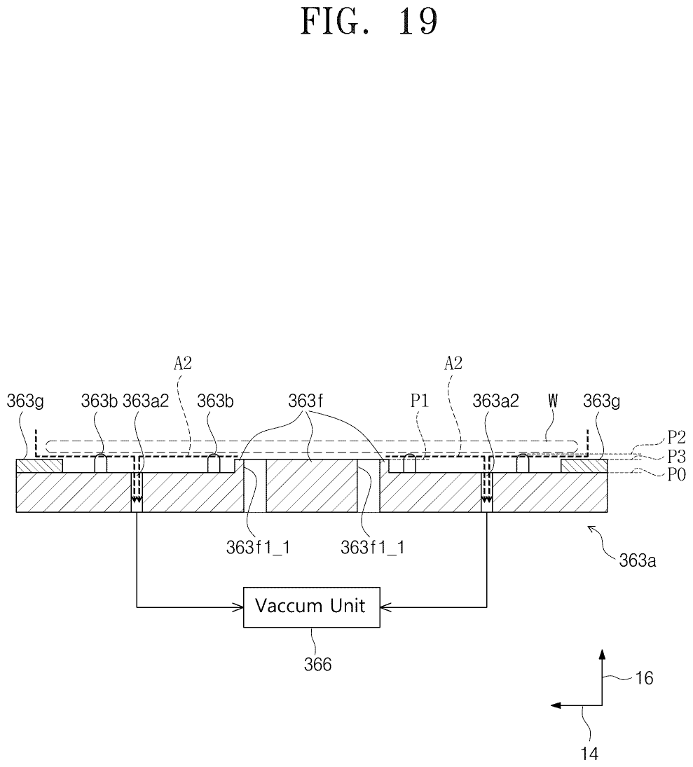

FIG. 19 is a longitudinal cross-sectional view of still another modified example of the blocking body illustrated in FIG. 12.

It is a matter of course that, as illustrated in FIG. 19, the outer wall 363g may be separately coupled to the top surface of the heating plate 363a, unlike the previous exemplary embodiments. Furthermore, the blocking body 363f may be implemented in various variations, such as the form in which the heating plate 363a is processed, so that the top end of the lift hole 363f1_1 is positioned higher than the top surface of the heating plate 363a, in contrast to the foregoing exemplary embodiments.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. A substrate treating apparatus comprising:
a heating unit including a heating plate for supporting and heating a substrate; and
a pressure reducing unit for applying a vacuum pressure to a space between a top surface of the heating plate and a substrate supported on the heating plate,
wherein the heating plate is provided with a lift hole, which is a movement passage for a lift pin to lift the substrate supported on the heating plate, and
a top end of the lift hole is provided at a position higher than the top surface of the heating plate.

2. The substrate treating apparatus of claim 1, wherein the heating unit further includes a support pin provided on the top surface of the heating plate and supporting the substrate, and
a top end of the lift hole is provided at a height lower than a top end of the support pin.

3. The substrate treating apparatus of claim 1, wherein the heating plate is formed with a through-hole penetrating in an up and down direction,
the heating unit further includes a blocking body in which the lift hole is formed, and
the blocking body is inserted into the through-hole.

4. The substrate treating apparatus of claim 3, wherein the blocking body is formed in a ring shape when viewed from above.

5. The substrate treating apparatus of claim 3, wherein the blocking body includes a body portion, and an extension portion positioned below the body portion,
the body portion is inserted into the through-hole such that a partial region thereof protrudes upwardly from the heating plate, and
when viewed from above, the extension portion is positioned below the heating plate and has a larger area than the through-hole.

6. The substrate treating apparatus of claim 3, wherein the blocking body includes a body portion, and an extension portion positioned on the body portion,
the body portion is inserted into the through-hole such that a partial region thereof protrudes upwardly from the heating plate, and
when viewed from above, the extension portion is positioned on the heating plate and has a larger area than the through-hole.

7. The substrate treating apparatus of claim 3, wherein the blocking body is detachably provided on the heating plate.

8. The substrate treating apparatus of claim 3, wherein the blocking body is formed of a material including a resin.

9. The substrate treating apparatus of claim 2, wherein the heating unit further includes a ring-shaped outer wall formed by upwardly protruding from the top surface of the heating plate and formed near an edge of the heating plate.

10. The substrate treating apparatus of claim 9, wherein an outer diameter of the outer wall is greater than an outer diameter of the substrate and an inner diameter of the outer wall is less than an outer diameter of the substrate.

11. The substrate treating apparatus of claim 9, wherein a top end of the outer wall is provided at the same height as a top end of the lift hole.

12. The substrate treating apparatus of claim 9, wherein a height of a top end of the outer wall is provided at a height lower than a height of a top end of the support pin.

13. The substrate treating apparatus of claim 9, wherein the outer wall extends from at least some of the regions of the heating plate to form a single part with the heating plate.

14. A heating unit for supporting a substrate and heating the substrate, the heating unit comprising:
a heating plate which is disposed under a substrate, heats the substrate, and is formed with a through-hole and a vacuum hole;
a support pin coupled to a top surface of the heating plate and supporting the substrate; and
a blocking body which is disposed on a top portion of the heating plate, is formed with a lift hole, and includes a body portion extending to the top portion of the heating plate at a height greater than a height of a top end of the through hole, and
the lift hole is a movement passage for a lift pin for lifting a substrate supported on the heating plate, and a top end is provided at a height greater than the top surface of the heating plate.

15. The heating unit of claim 14, wherein a top end of the lift hole is provided at a height lower than a top end of the support pin.

16. The heating unit of claim 14, wherein the blocking body is inserted into the through-hole.

17. The heating unit of claim 14, wherein the blocking body is formed in a ring shape when viewed above.

18. The heating unit of claim 14, wherein the blocking body is detachably provided from the heating plate.

19. The heating unit of claim 14, wherein the blocking body is formed of a material including a resin.

20. A heating unit for supporting a substrate and heating the substrate, the heating unit comprising:
a heating plate which is disposed under the substrate, heats the substrate, and is formed with through-holes and vacuum holes;
a support pin coupled to a top surface of the heating plate and supporting the substrate;
a ring-shaped outer wall formed by upwardly protruding from the top surface of the heating plate and formed near an edge of the heating plate; and
a blocking body which is formed of a material including a resin and includes a body portion that is detachably connected with the heating plate, is inserted into the through-hole, is disposed in a top portion of the heating plate, is formed in a ring shape having a lift hole when viewed above, and is positioned in the top portion of the heating plate at a height greater than a height of a top end of the through hole, and an extension portion that extends laterally from the body portion and is pressed against or coupled to a bottom surface of the heating plate, and
the lift hole has a top end provided at a position lower than a top end of the support pin, is a movement passage for a lift pin for lifting a substrate supported on the heating plate, and has the top end provided at a position higher than a top surface of the heating plate.
